(19) United States
(12) Patent Application Publication
(10) Pub. No.: US 2026/0066895 A1
(43) Pub. Date: Mar. 5, 2026

(54) WIRELESS POWERED APPLIANCE POWER MANAGEMENT SYSTEMS, DEVICES, AND METHODS THEREOF

(71) Applicant: GD Midea Air Conditioning Equipment Co., Ltd., Beijiao (CN)

(72) Inventors: Craig Benjamin Williams, Louisville, KY (US); John K. Hooker, Louisville, KY (US)

(73) Assignee: Midea Group Co., Ltd., Foshan (CN)

(21) Appl. No.: 18/821,338

(22) Filed: Aug. 30, 2024

(51) Int. Cl. H03K 17/22; H02J 50/10

(52) U.S. Cl. CPC H03K 17/22; H02J 50/10; H02J 2105/42; H03K 2017/226

(57) ABSTRACT

Certain aspects of the present disclosure provide techniques for power management of a wireless powered appliance. A wireless powered appliance includes a wireless power receiver configured to generate electric power from a magnetic field emitted from a wireless power transmitter. The electric power comprises a supply voltage. The wireless powered appliance further includes power level detection circuit comprising circuit components configured to generate one or more output signals. The one or more output signals correspond to the supply voltage exceeding one or more thresholds. The wireless powered appliance further includes a power transition stabilizer circuit configured to receive the one or more output signals and the supply voltage. The power transition stabilizer circuit includes one or more electrical loads configured to electrically couple to the supply voltage based on the one or more output signals such that the supply voltage is reduced by the one or more electrical loads.

### INTRODUCTION

### Field of the Disclosure

Aspects of the present disclosure relate to wireless powered appliance power management.

### Description of Related Art

Appliances, such as blenders, air fryers, slow-cookers, and the like are typically wired appliances which include a cord connected directly from the appliance to an alternating current power source. However, there are a growing number of appliances which are configured to receive power from a wireless power transmitter through a wireless power receiver within the appliance. Unlike wired appliances, wireless powered appliances may be communicatively decoupled from the wireless power transmitter or incur a delay in communicating power requirement to the wireless power transmitter from which the wireless powered appliance receives wireless power. Changes in the required power of a wireless powered appliance can change many times during operation. For example, turning on or off loads such as heating elements, motors, and the like each may require a different amount of power. Changes in the required power of a wireless powered appliance provide challenges to power management of wireless powered appliances. Accordingly, there is a need for power management techniques that enable continuous and matched power levels between the wireless power transmitter and the wireless power receiver of wireless powered appliances.

### SUMMARY

One aspect provides a wireless powered appliance, comprising: one or more wireless power receivers configured to generate electric power from a magnetic field emitted from one or more wireless power transmitters, wherein the electric power comprises a supply voltage; a power level detection circuit comprising circuit components configured to generate one or more output signals at one or more output terminals, wherein the one or more output signals correspond to the supply voltage exceeding one or more thresholds; and a power transition stabilizer circuit configured to receive the one or more output signals from the power level detection circuit and the supply voltage from the one or more wireless power receivers, the power transition stabilizer circuit comprising one or more electrical loads configured to electrically couple to the supply voltage based on the one or more output signals such that the supply voltage is reduced by the one or more electrical loads.

Another aspect provides a method for power management of a wireless powered appliance, the method comprising: receiving, through one or more wireless power receivers, electric power from a magnetic field emitted from one or more wireless power transmitters, wherein the electric power comprises a supply voltage; generating, with a power level detection circuit, one or more output signals corresponding to the supply voltage exceeding one or more thresholds; and reducing the supply voltage with a power transition stabilizer circuit configured to electrically couple the supply voltage to one or more electrical loads based on the one or more output signals.

Other aspects provide: one or more apparatuses operable, configured, or otherwise adapted to perform any portion of any method described herein (e.g., such that performance may be by only one apparatus or in a distributed fashion across multiple apparatuses); one or more non-transitory, computer-readable media comprising instructions that, when executed by one or more processors of one or more apparatuses, cause the one or more apparatuses to perform any portion of any method described herein (e.g., such that instructions may be included in only one computer-readable medium or in a distributed fashion across multiple computer-readable media, such that instructions may be executed by only one processor or by multiple processors in a distributed fashion, such that each apparatus of the one or more apparatuses may include one processor or multiple processors, and/or such that performance may be by only one apparatus or in a distributed fashion across multiple apparatuses); one or more computer program products embodied on one or more computer-readable storage media comprising code for performing any portion of any method described herein (e.g., such that code may be stored in only one computer-readable medium or across computer-readable media in a distributed fashion); and/or one or more apparatuses comprising one or more means for performing any portion of any method described herein (e.g., such that performance would be by only one apparatus or by multiple apparatuses in a distributed fashion). By way of example, an apparatus may comprise a processing system, a device with a processing system, or processing systems cooperating over one or more networks.

The following description and the appended figures set forth certain features for purposes of illustration.

### BRIEF DESCRIPTION OF DRAWINGS

The appended figures depict certain features of the various aspects described herein and are not to be considered limiting of the scope of this disclosure.

FIG. 1 depicts an illustrative wireless powered appliance configured to receive power from a wireless power generation device.

FIG. 2 depicts an illustrative block diagram of a wireless powered appliance and a wireless power generation device.

FIG. 3A depicts an example implementation of the power level detection circuit.

FIG. 3B depicts another example implementation of the power level detection circuit.

FIG. 4A depicts an illustrative diagram of two example power transition stabilizer circuits.

FIG. 4B depicts an illustrative diagram of the power transition stabilizer circuit including a pulse extender circuit.

FIG. 4C depicts an illustrative example of a power transition stabilizer circuit including a level shift buffer circuit.

FIG. 5 depicts an illustrative diagram of an implementation of the power management circuitry in a wireless powered appliance.

FIG. 6 depicts a method for power management of a wireless powered appliance.

### DETAILED DESCRIPTION

Aspects of the present disclosure provide systems, devices, and methods for managing power of wireless powered appliances. Aspects will be described with reference to the drawings, where like structure is indicated with like reference numerals.

### Example Wireless Powered Appliance

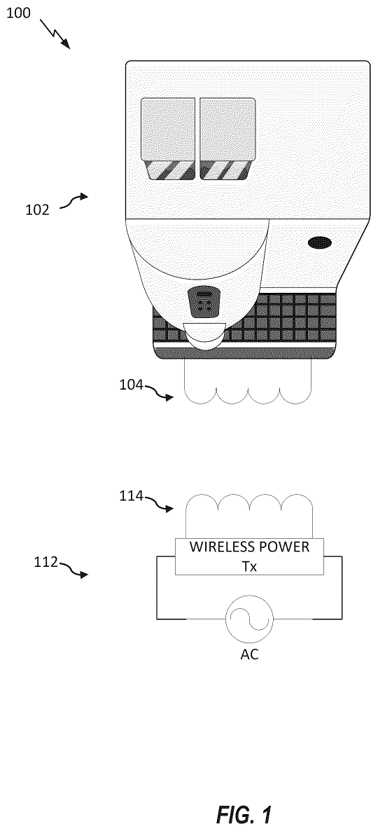

FIG. 1 depicts an illustrative wireless powered appliance 102 configured to receive power from a wireless power generation device 112. The wireless powered appliance 102 includes a wireless power receiver 104 that when magnetically coupled with a wireless power transmitter 114, is capable of converting the magnetic field generated by the wireless power transmitter into electric power through the wireless power receiver 104.

Wireless powered appliances may include appliances such as coffee makers, air fryers, blenders, slow-cookers, toasters, food processors, and the like. Wireless powered appliances, unlike wired appliances, receive power to operate through wireless power transmission. Accordingly, the amount of electric power the wireless power receiver 104 harvests through its receiver coils at any given instance may depend at least in part on the strength of the magnetic field that is generated by the wireless power transmitter 114.

Successful transmission of wireless energy depend on a variety of factors. For example, some factors include how well the coils of the wireless power receiver 104 and the coils of the wireless power transmitter 114 magnetically couple. Magnetic coupling can depend on the coil structure of each the wireless power receiver 104 and the wireless power transmitter 114 and/or alignment factors such as the distance between the devices, the angle of the coils with respect to each other, the alignment of the coils along a central axis, and/or other factors. Changes in the position and/or orientation of the coils of the wireless power receiver 104 and the coils of the wireless power transmitter 114 can cause poor power regulation and leading to events such as power surges.

Additionally, operational aspects of the wireless powered appliance can also lead to power surges. In certain aspects, the wireless powered appliance communicates power requirements to the wireless power generation device 112. However, there may be delays between communication of the power requirement of the wireless powered appliance and activation of the load components of the wireless powered appliance. For example, a wireless powered appliance, such as an air fryer, may periodically switch ON and OFF a heating element (e.g., a load component). When the heating element is switched on, the wireless powered appliance requires more power to be delivered from the wireless power generation device 112 to the wireless power receiver 104. When there is a misalignment in the timing of power being available for harvesting by the wireless power receiver 104 and activation of the load component, the electrical component of the wireless powered appliance can experience a power surge. Power surges can reduce the life of electrical components and even render the electrical components non-functional.

Aspects of the present disclosure are directed to managing power surges, for example, caused by influxes of additional power generated by the wireless power generation device 112 and harvested by the wireless power receiver 104 before the wireless powered appliance 102 needs the increase in power. The aforementioned instances may be referred to as load step transitions. It should be understood that load step transitions can refer to both changes in operational power requirements of the wireless powered appliance 102 as well as external factors such as a change in position or orientation of the wireless powered appliance with respect to the wireless power generation device 112.

For wired devices there are commonly used components to suppress or eliminate power surges. However, power surges for wired devices are short in duration (e.g., a few micro seconds). Whereas, load step transitions for wireless powered appliances may be longer in duration, for example, lasting multiple milliseconds (e.g., one to tens of milliseconds). The longer duration of the load step transitions experienced by wireless powered appliances makes the components commonly used for wired devices ineffective. Some examples of the commonly used components for wired devices include transient voltage suppression devices, such as metal oxide varistors (MOVs) or transient voltage surge suppressors (TVSS), fuse devices, emergency brake signaling, relays, or the like. In some instances, these components are unable to maintain protection for the duration of the load step transition. In other instances, the duration of the load step transition coupled with the frequency of load step transition events can negatively impact the life cycle of the device thereby rendering it ineffective before the end of the wireless powered appliance's lifecycle.

More specifically, for a wired appliance, a transient voltage device like a MOV or TVSS is typically used to protect again short duration (e.g., 20 μs) voltage spike on AC line. These devices are typically high impedance while the voltage is below a threshold. If the voltage exceeds the threshold, the device changes to low impedance to short out in order to power clamp the voltage until the voltage drops or device fails.

For a wireless powered appliance, load step transitions can be normal operation thus multiple opportunities for voltage surge can be common during operation. Additionally, the load step transitions can last much longer than typical surges seen on AC wired devices. For example, in some instances load step transitions can last multiple milliseconds, for example, about 10 ms or more before anything can be done to resolve. Therefore, traditional transient voltage suppression is not an option for wireless powered appliances 102.

Fuse devices are configured to open up to prevent additional power from flowing into electronics. A fuse can open quickly to reduce or prevent damage to electronics. A fuse may be used to open the power coil of the wireless power receiver 104 quickly to remove power from wireless power receiver 104 and protect electronics. However, the quick removal of power from the wireless power receiver 104 results in a power surge that can damage the wireless power transmitter 114. Accordingly, a fuse is not an option as preventing damage to the wireless power receiver 104 can causes damage to the wireless power transmitter 114.

Emergency brake signaling between the wireless power receiver 104 and the wireless power transmitter 114 can take multiple milliseconds to transmit, receive, decode, and enact a shutdown. In certain aspects, emergency brake signaling between the wireless power receiver 104 and the wireless power transmitter 114 may encompass various signals, such as a stop power signal, a reduce power signal, or the like. The stop power signal may cause the wireless power transmitter 114 to stop the generation and emission of wireless power. The reduce power signal may cause the wireless power transmitter 114 to reduce amount of generated and emitted wireless power. For example, amount to reduce the wireless power by may be indicated in the reduce power signal or may be a predefined value configured in the wireless power transmitter 114 that is implemented in response to receipt of the reduce power signal. In certain aspects, the amount to reduce the wireless power generated and emitted by the wireless power transmitter 114 may be about 10%, about 20%, about 30%, about 40%, about 50%, about 60%, about 70%, about 80%, about 90% or less than 100%, or any value between about 1% and about 99%. The ability to utilize emergency brake signaling can depend on whether the wireless power receiver 104 and the wireless power transmitter 114 can effectively communicate with each other. Accordingly, emergency brake signaling may not a viable option for achieving a quick response to the load step transition.

In some load suppression techniques, a relay may be used to switch a large load, but a relay is a slow device taking multiple milliseconds to open or close. This relatively long time to operate prevents the relay from being able to responding fast enough to prevent damage to electronics of a wireless powered appliance.

Aspects, which will be described in detail herein, provide techniques for managing power including load step transitions of wireless powered appliances quickly in order to reduce the chance for damage or prevent damage to electronics of a wireless powered appliance 102.

For a wireless power system, a transmitter sources energy that is coupled into the wireless powered appliance and must be used by the wireless powered appliance. This power is negotiated by communicating power expectation between the wireless powered appliance 102 and the wireless power generation device 112 and will typically match, however some power transitions, for example, but not limited to large power transitions, such as activation of a heating element, a motor, a fan, a pump, or the like can be particularly challenging to manage. Aspects provided herein quickly manages the power mismatch during these load step transitions to reduce or prevent damage to the electronics.

For example, during normal operation, an air fryer may always run a fan but turns a heater ON and OFF via a relay to control cooking temperature. These cycles cause large change in power consumption, for example 1100 W, when the heater is ON and 100 W when the heater is OFF. Each power change needs to be coordinated between the wireless power generation device 112 and wireless powered appliance 102. Additionally, even with coordination between the wireless power generation device 112 and wireless powered appliance 102 there is an opportunity for a temporary mismatch in power delivered and harvested (e.g., excess power) and power for consumption (e.g., before the heater is activated).

### Example Wireless Powered Appliance Including Power Management Circuitry

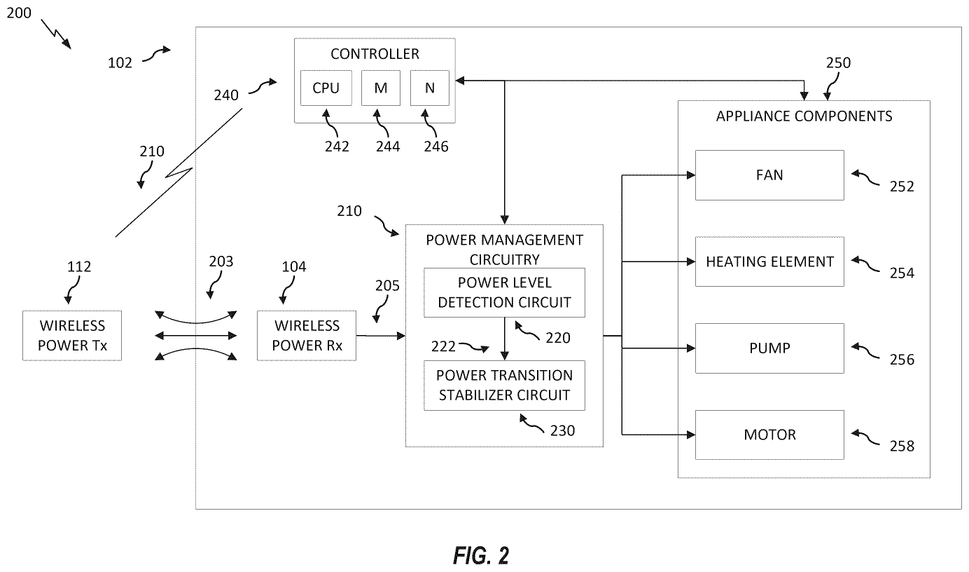

FIG. 2 depicts an illustrative block diagram 200 of a wireless powered appliance 102 and a wireless power generation device 112. As discussed with reference to FIG. 1, the wireless powered appliance 102 includes a wireless power receiver 104 that when magnetically coupled with a wireless power transmitter 114, is capable of converting the magnetic field 203 generated by the wireless power transmitter into electric power through the wireless power receiver 104. The electric power generated by the wireless power receiver 104 is referred to as the “supply voltage” herein. While description of aspects herein refer to techniques for managing the supply voltage component of the electric power, it should be understood that managing the supply current component of the electric power can also be achieved through the techniques described herein by methods of quantifying current values known in the art, such as measuring the voltage drop across a known resistance.

In certain aspects, the electric power generated by the wireless power receiver 104 may be managed by the power management circuitry 210 of the wireless powered appliance 102. The power management circuitry 210 can include multiple components for rectifying, conditioning, monitoring, diverting, and directing electric power for the various components of the wireless powered appliance 102. Aspects of the present disclosure relate to a power level detection circuit 220 and a power transition stabilizer circuit 230. The power level detection circuit 220 may include circuit components configured to generate one or more output signals at one or more output terminals. The one or more output signals correspond to detection of events where the supply voltage 205 exceeds one or more thresholds. The power transition stabilizer circuit 230 may be configured to receive the one or more output signals 222 from the power level detection circuit 220 and the supply voltage 205 from the one or more wireless power receivers 104. The power transition stabilizer circuit 230 may include one or more electrical loads configured to electrically couple to the supply voltage 205 based on the one or more output signals 222 such that the supply voltage 205 is reduced by the one or more electrical loads. The supply voltage 205 being greater than one or more of the thresholds may indicate the occurrence of a load step transition.

In certain aspects, the wireless powered appliance 102 includes a controller 240. The controller 240 may include one or more processors 242, a non-transitory computer readable memory 244 (also referred to herein as one or more memories), and/or network interface hardware 246. These and other components of the wireless powered appliance 102 may be communicatively connected to each other via a communication path. It should be noted that non-transitory computer readable memory 244 may include volatile and/or non-volatile memory or storage.

The communication path may be formed from any medium that is capable of transmitting a signal such as, for example, conductive wires, conductive traces, optical waveguides, or the like. The communication path may also refer to the expanse in which electromagnetic radiation and their corresponding electromagnetic waves traverses. Moreover, the communication path may be formed from a combination of mediums capable of transmitting signals. In one embodiment, the communication path comprises a combination of conductive traces, conductive wires, connectors, and buses that cooperate to permit the transmission of electrical data signals to components such as processors, memories, sensors, input devices, output devices, and communication devices. Accordingly, the communication path may comprise a bus. Additionally, it is noted that the term “signal” means a waveform (e.g., electrical, optical, magnetic, mechanical or electromagnetic), such as DC, AC, sinusoidal-wave, triangular-wave, square-wave, vibration, and the like, capable of traveling through a medium. As used herein, the term “communicatively coupled” means that coupled components are capable of exchanging signals with one another such as, for example, electrical signals via conductive medium, electromagnetic signals via air, optical signals via optical waveguides, and the like.

The controller 240 may be any device or combination of components comprising one or more processors 242 and non-transitory computer readable memory, referred to herein as one or more memories 244. The one or more processors 242 may be any device capable of executing the processor-executable instructions stored in the one or more memories 244. Accordingly, the one or more processors 242 may be an electric controller, an integrated circuit, a microchip, a computer, or any other computing device. The one or more processors 242 are communicatively coupled to the other components of the wireless powered appliance 102 by the communication path. Accordingly, the communication path may communicatively couple any number of processors 242 with one another, and allow the components coupled to the communication path to operate in a distributed computing environment. Specifically, each of the components may operate as a node that may send and/or receive data.

The one or more memories 244 may comprise RAM, ROM, flash memories, hard drives, or any non-transitory memory device capable of storing processor-executable instructions such that the processor-executable instructions can be accessed and executed by the one or more processors 242. The machine-readable instruction set may comprise logic or algorithm(s) written in any programming language of any generation (e.g., 1GL, 2GL, 3GL, 4GL, or 5GL) such as, for example, machine language that may be directly executed by the one or more processors 242, or assembly language, object-oriented programming (OOP), scripting languages, microcode, etc., that may be compiled or assembled into processor-executable instructions and stored in the one or more memories 244. Alternatively, the processor-executable instructions may be written in a hardware description language (HDL), such as logic implemented via either a field-programmable gate array (FPGA) configuration or an application-specific integrated circuit (ASIC), or their equivalents. Accordingly, the functionality described herein may be implemented in any conventional computer programming language, as pre-programmed hardware elements, or as a combination of hardware and software components.

In some aspects, the network interface hardware 246 may enable the wireless powered appliance 102 to communicate with other devices, for example, including the wireless power generation device 112. The network interface hardware 246 may be coupled to the communication path and communicatively coupled to the controller 240. The network interface hardware 246 may be any device capable of transmitting and/or receiving data with a network or directly with another vehicle, such as equipped with a vehicle-to-vehicle communication system. Accordingly, network interface hardware 246 can include a communication transceiver for sending and/or receiving any wired or wireless communication. For example, the network interface hardware 246 may include an antenna, a modem, LAN port, Wi-Fi card, WiMax card, mobile communications hardware, near-field communication hardware, satellite communication hardware and/or any wired or wireless hardware for communicating with other networks and/or devices. In one embodiment, network interface hardware 246 includes hardware configured to operate in accordance with the Bluetooth wireless communication protocol. In another embodiment, network interface hardware 246 may include a Bluetooth send/receive module for sending and receiving Bluetooth communications to/from a network and/or another vehicle.

The controller 240 may control activation and deactivation of the appliance components 250 and when power from the power management circuitry 210 should be provided to the various appliance components.

Once one or more of the appliance components 250 are activated and ready to receive power, for example, once a relay controlling activation of the appliance component 250 closes, then the power management circuitry delivers electric power to the one or more appliance components 250. Appliance components 250 may include one or more fans 252, one or more heating elements 254, one or more pumps 256, one or more motors 258, and/or the like.

### Example Power Level Detection Circuits

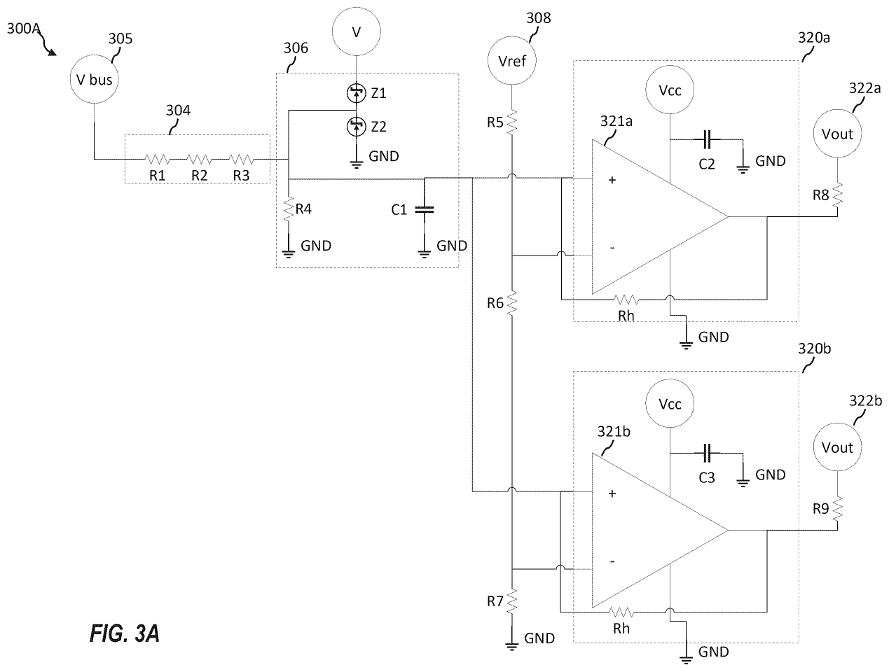

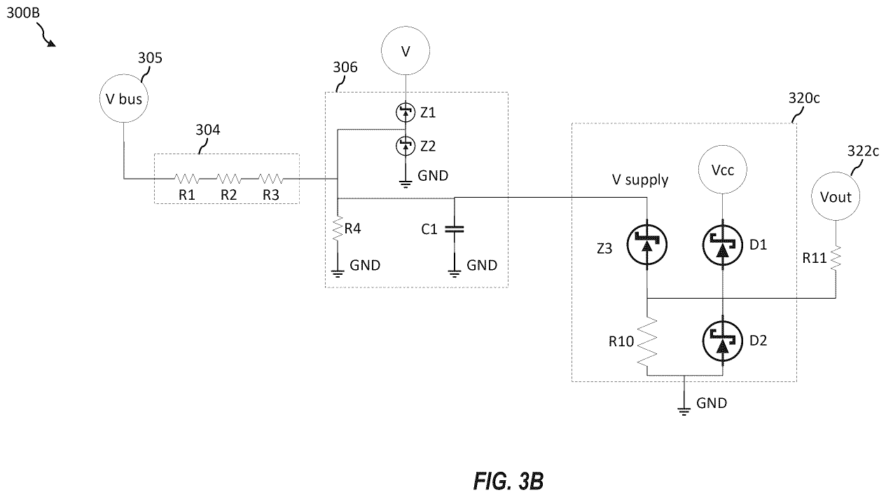

FIGS. 3A-3B depict illustrative diagrams of example implementations of the power level detection circuit 220, referred to in FIGS. 3A-3B as power level detection circuits 320a, 320b, and 320c. FIG. 3A depicts a comparator based implementation of the power level detection circuit 320a, 320b. In certain aspects, the power management circuitry 210 may include various components and circuits configured to measure the supply voltage 305, condition to the supply voltage 305 to a value compatible with analog or digital logic, and/or filter the supply voltage 305 to reduce noise. For example, as depicted in FIG. 3A, the power management circuitry 210 may include a voltage divider circuit 304. The voltage divider circuit 304 may include one or more resistor elements R1, R2, R3 configured by means known in the art to measure and reduce the magnitude of the supply voltage 305. The power management circuitry 210 may also include a noise filter 306. An example noise filter 306 is depicted in FIG. 3A, however, other implementations may also be utilized. In certain aspects, the noise filter 306 includes a reference voltage V electrically coupled to a first diode Z1 (e.g., a Zener diode or another type of diode) with the supply voltage 305 fed into the opposing end of the first diode Z1 and a first end of the second diode Z2 (e.g., a Zener diode or another type of diode). The pair of diodes enable logic leveling of the supply voltage 305 such that the magnitude of the supply voltage 305 does not exceed a voltage level of the logic components. In certain aspects, the noise filter 306 may also include a resistor-capacitor (RC) circuit to reduce fluctuations in the supply voltage 305. It should be understood that some aspects may include one of the voltage divider circuit 304 or the noise filter 306 or both or neither.

The power management circuitry 210 further includes one or more power level detection circuits 320a, 320b. Multiple power level detection circuits 320a, 320b may be implemented to monitor and handle different respective magnitudes of supply voltage 305. For example, a first power level detection circuit 320a may be configured to determine whether the supply voltage 305 exceeds a first threshold, while a second power level detection circuit 320b may be configured to determine whether the supply voltage 305 exceeds a second threshold, which may be greater than the first threshold. Accordingly, each of the one or more power level detection circuits 320a, 320b may generate a respective output signal to be utilized by the power transition stabilizer circuit 230 to activate, connect the appropriate electrical load to the electric power generated by the wireless power receiver 104 in order to absorb the excess power during an event, such as a load step transition.

The first power level detection circuit 320a and the second power level detection circuits 320b include similar architecture, so only the first power level detection circuit 320a will described in detail. It should be understood that more than two power level detection circuits 320a, 320b can be implemented within the power management circuitry 210.

In certain aspects, the first power level detection circuit 320a includes a comparator 321a (e.g., the second power level detection circuit 320b includes a comparator 321b). The comparator 321a, 321b may be an operational amplifier comprising a positive input terminal (+), a negative input terminal (−), a positive side power supply terminal, a negative side power supply terminal, and an output terminal. The positive input terminal (+) may be electrically coupled to the supply voltage 305 or a measured value of the supply voltage 305. The negative input terminal (-) may be electrically coupled to one of the one or more reference voltages corresponding to a respective one of the one or more thresholds. The reference voltages may be generated from a common reference voltage supply 308 that is voltage divided by a series of resistors having resistance values configured to generate the respective reference voltage for the comparator 321a, 312b. For example, resistors R5 and R6 cause the voltage from the common reference voltage supply 308 to drop to a first reference voltage input to the negative input terminal (−) of comparator 321a. Additionally, resistors R6 and R7 cause the voltage from the common reference voltage supply 308 to drop to a second reference voltage input to the negative input terminal (−) of comparator 321b.

The positive side power supply terminal may be coupled to a voltage source Vcc and the negative side power supply terminal may be connected to ground or a sink.

The comparator 321a compares the supply voltage 305 to the first reference voltage to generate a determination as to whether the supply voltage 305 exceeds the first reference voltage corresponding to the first threshold by way of a first output signal 322a. The output signal 322a may be an analog voltage value. Comparator 321b operates in a similar manner to generate a determination as to whether the supply voltage 305 exceeds the second reference voltage corresponding to the second threshold by way of a second output signal 322b.

The one or more output signals 322a, 322b are utilized to cause the power transition stabilizer circuit 230 to connect one or more electrical loads to the electric power generated by the wireless power receiver 104.

In certain aspects, controller 240 may be configured with additional circuitry such as an analog-to-digital converter and other components to monitor a transition time of load step transition reaching one or more threshold values. The transition time measurement may be utilized by the controller 240 to determine the magnitude of the power level to be absorbed. In certain aspects, the controller 240 may measure the rate of change (e.g., the transition time) in voltage, V, on a capacitor electrically coupled to the wireless power receiver 104, which indicates the rate of change of charge, Q (e.g., V voltage V=charge Q/coulombs C). For example, a slow transition time may indicate less of an overshoot in power by the load step transition and thus requiring less power to be absorbed. However, a fast transition time may indicate a large overshoot in power by the load step transition and thus requiring more power to be absorbed. The controller 240 can electronically couple one or more electrical loads to the electric power generated by the wireless power receiver 104 based on the determined magnitude of the power level to be absorbed. That is, the measured time can be utilized by the controller 240 to determine the size of the one or more electrical loads to be applied to absorb power. The controller 240 may signal to the power transition stabilizer circuit 230 to electrically couple one or more electrical loads to the electric power supply generated by the wireless power receiver 104 in order to reduce and/or absorb the supply voltage 305 and supply current. By optimizing the size of the one or more electrical loads a reset of the power supply circuit can be avoided and thus improve user experience and protect the electrical components of the wireless powered appliance 102.

In certain aspects, a resistor Rh is coupled between the positive input terminal (+) and the output terminal of the comparator 321a (likewise for comparator 321b) to minimize hysteresis. By minimizing hysteresis, a fast response of the comparator 321a, 321b can be maintained. Moreover, fewer ON/OFF transitions of the electric switch may be caused by the one or more output signals 322.

In certain aspects, the power management circuitry 210 may utilize other components for determining whether a supply voltage 305 exceeds one or more thresholds. FIG. 3B depicts a diode based implementation of the power level detection circuit 320c. In such an implementation, the supply voltage 305 or a measured value of the supply voltage 305 is electrically coupled to a cathode of a Zener diode Z3. When the supply voltage 305 is greater than the breakdown voltage of the Zener diode Z3, the Zener diode Z3 begins to conduct. Resistor R10 causes the voltage value at the anode of the Zener diode Z3 to increase to a high value, otherwise the voltage at this point remains zero or close to zero. In some aspects, a pair of Schottky diodes may be electrically coupled as depicted in FIG. 3B. For example, the anode of the Zener diode may be coupled an anode of the first Schottky diode D1 and a cathode of a second Schottky diode D2. A reference voltage supply Vcc may be coupled to a cathode of the first Schottky diode. The pair of Schottky diodes logic level the voltage of the output signal within a voltage logic range. The voltage logic range may be zero to 3.3 V, zero to 5 V, zero to 12 V, or any other logic range compatible with the logic and switch components of the power management circuitry 210.

It should be understood that power management circuitry 210 may implement one or more variations of the one or more power level detection circuits 320a, 320b, and 320c. Accordingly, aspects may be implemented interchangeably and in combination.

### Example Power Transition Stabilizer Circuits

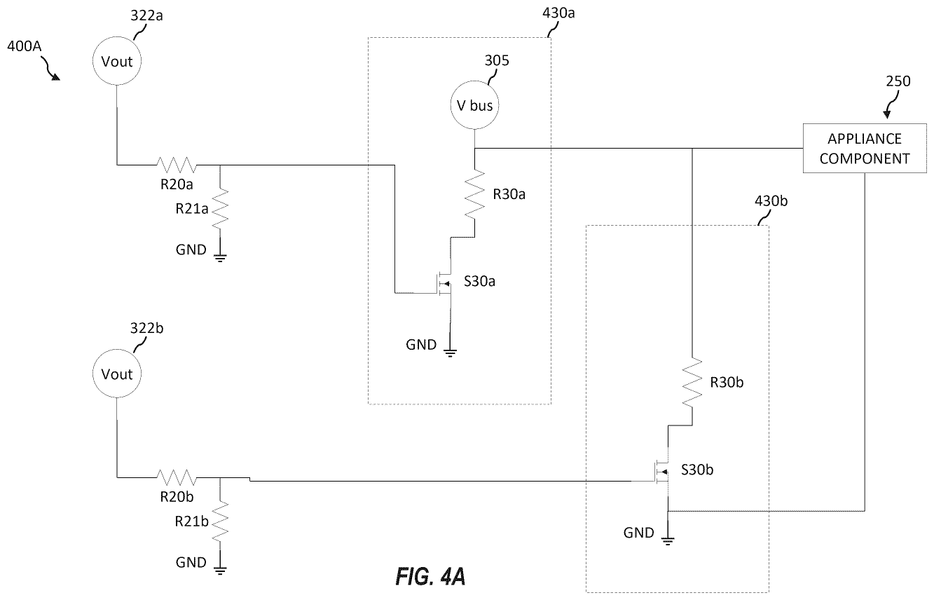

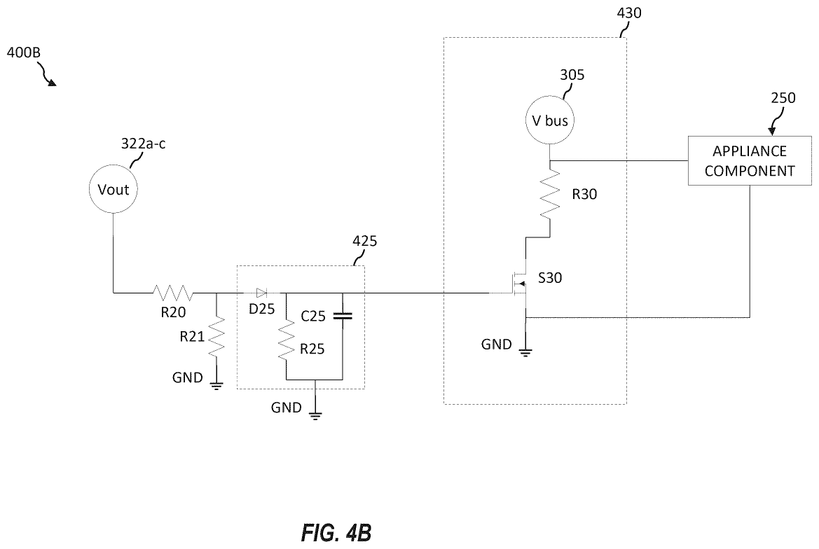

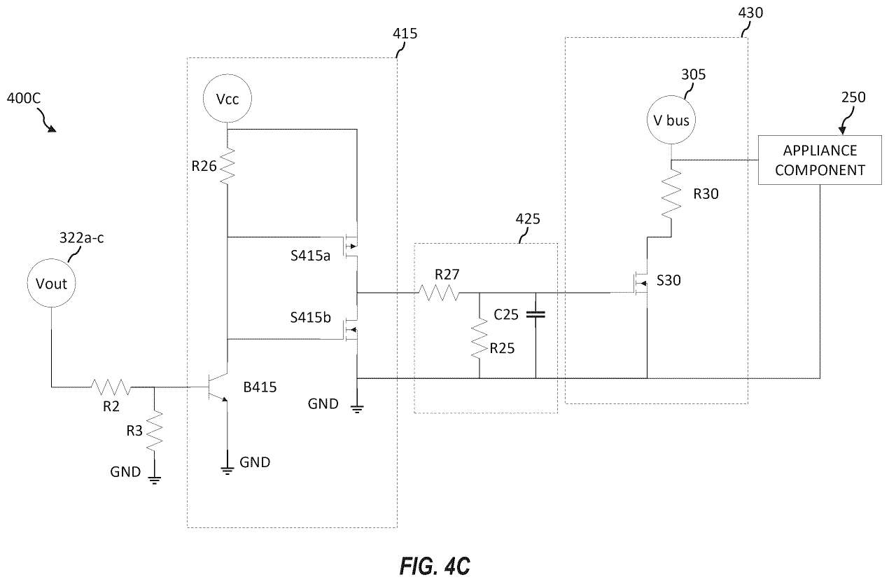

FIGS. 4A-4C depict illustrative diagrams of example implementations of the power transition stabilizer circuit 230, referred to in FIGS. 4A-4C as power transition stabilizer circuit 430a and 430b. FIG. 4A depicts two power transition stabilizer circuits 430a, 430b, each configured to electrically couple a different electrical load (e.g., resistors R30a, R30b) to the electric power supply Vbus generated by the wireless power receiver 104 based on the one or more output signals 322a, 322b, for example, generated by the power level detection circuits 320a, 320b of FIG. 3A.

In certain aspects, the power management circuitry 210 may include one or more power transition stabilizer circuits 430a, 430b each having the capability of electrically coupling one or more electrical loads to the electric power supply Vbus to reduce and/or absorb the supply voltage 305 and supply current until the appliance component 250 is available to consume the electric power supply Vbus. In certain aspects, the one or more electrical loads may include one or more resistors, one or more capacitors, one or more inductors, one or more power transistors, one or more lamps (e.g., a neon 1 amp), one or more batteries, or other power absorption components or circuits. For example, a snubber circuit or other type of power absorption circuit may be utilized to form the one or more electrical loads. In certain aspects, the one or more electrical loads (e.g., resistors R30a, R30b) may be sized to correspond to one or more of the appliance components such as, the one or more fans 252, the one or more heating elements 254, the one or more pumps 256, the one or more motors 258, and/or the like. For example, one of the one or more electrical loads (e.g., resistors R30a, R30b) may be a resistor having a resistance between about 28 ohms and 33 ohms, such that the electrical load corresponds to the one or more heating elements 254, for example having an equivalent resistance of about 30 ohms. In certain aspects, the one or more electrical loads may be configured to correspond to the impedance (e.g., including one or both resistance or reactance components) of the one or more of the appliance components. In some aspects, the impedance may be the ON impedance. ON impedance refers to the impedance (e.g., also referred to as equivalent impedance) of an appliance component (e.g., appliance components 250 discussed with reference to FIG. 2) when in an operating state. Equivalent impedance refers to the impedance of an element, such as the appliance component, that can be used to replace a collection of elements at a pair of nodes without affecting any of the voltages and currents throughout the rest of the circuit.

The one or more power transition stabilizer circuits 430a, 430b may be configured to electrically couple the electric power supply Vbus to the one or more electrical loads (e.g., resistors R30a, R30b) based on the one or more output signals 322a, 322b activating one or more electronic switches S30a, S30b. The one or more electronic switches S30a, S30b may be a component such as a metal-oxide-semiconductor field-effect transistor (MOSFET). The one or more output signals 322a, 322b may control the gate of the MOSFET thereby, when active, causing the electric power supply Vbus and the one or more electrical loads (e.g., resistors R30a, R30b) to complete a circuit such that current passes through the one or more electrical loads (e.g., resistors R30a, R30b) and reduces the supply voltage 305.

In certain aspects, a voltage divide circuit (e.g., resistors R20a, R21a and/or resistors R20b, R21b) may be implemented to adjust the voltage level of the one or more output signals 322a, 322b to a value that enables activation of the respective one or more electronic switches S30a, S30b.

FIG. 4B depicts an illustrative example of a power transition stabilizer circuit 430, which corresponds to the FIG. 4A, but further includes a pulse extender circuit 425. In certain aspects, there is an advantage to causing the one or more electrical loads to remain connected to the electric power supply Vbus for a predetermined amount of time. For example, a heating element 254 may not immediately require all the power delivered by the electric power supply Vbus as it activates (e.g., heats up). In such instances, a pulse extender circuit 425 may be implemented in order to keep the one or more electronic switches S30 active for the predetermined amount of time. This may be accomplished with a variety of circuits. For example, as depicted in FIG. 4B, an RC circuit, the values of the resistor R25 and the capacitor C25 may be selected to generate a time delay corresponding to the predetermined amount of time. Diode D25 may be included to prevent the RC circuit from discharging to ground through resistor R21, instead of keeping the gate of the electronic switch S30 active until the capacitor C25 discharges. In certain aspects, a 555 timer circuit may utilized to achieve the same objective of maintaining activation of the gate of the electronic switch S30 for the predetermined amount of time.

FIG. 4C depicts an illustrative example of a power transition stabilizer circuit 430 including a level shift buffer circuit 415. The level shift buffer circuit 415 is configured to raise the voltage of the one or more output signals 322a-c to a turn ON voltage of the electronic switch S30. In such aspects, the one or more output signals 322a-c may directly drive the electronic switch S30 with limited filtering to achieve a quick response. The illustrative level shift buffer circuit 415 includes a resistor R26 coupled to a voltage source Vcc and a bipolar junction transistor B415 which is activated by the one or more output signals 322a-c. MOSFETS S415a and S415b are configured in a voltage push-pull configuration whereby the drain of each is electrically coupled to the gate of the electronic switch S30 of the power transition stabilizer circuit 430.

Additionally, FIG. 4C depicts another example implementation of an RC circuit depicted and described with reference to FIG. 4B. However, in the implementation depicted in FIG. 4C, the RC circuit includes a resistor R27 in place of diode D25 since diode D25 is not needed in view of the push-pull MOSFET configuration.

In certain aspects, the controller 240 may be configured to record occurrences of load step transitions and the corresponding information, such as the supply voltage 305 values and appliance component 250 to be activated. In some aspects, the controller 240 may be configured to generated and transmit a signal to the wireless power generation device 112 to stop the generation of wireless power. In some aspects, the controller 240 may be configured to generated and transmit a signal to the wireless power generation device 112 to reduce the generation of wireless power. Such occurrences may be needed when the controller 240 determines that the wireless powered appliance is not operating correctly, for example, the appliance component has failed, and the electrical load should not continue to absorb the electrical power.

In certain aspects, the controller 240 may be configured to cause the power management circuitry to switch between one or more electrical loads to distribute the electrical power supply between various electrical loads. In some aspects, the controller 240 may implement a pulse-width modulation control of distribution between the one or more electrical loads.

### Example Wireless Powered Appliance

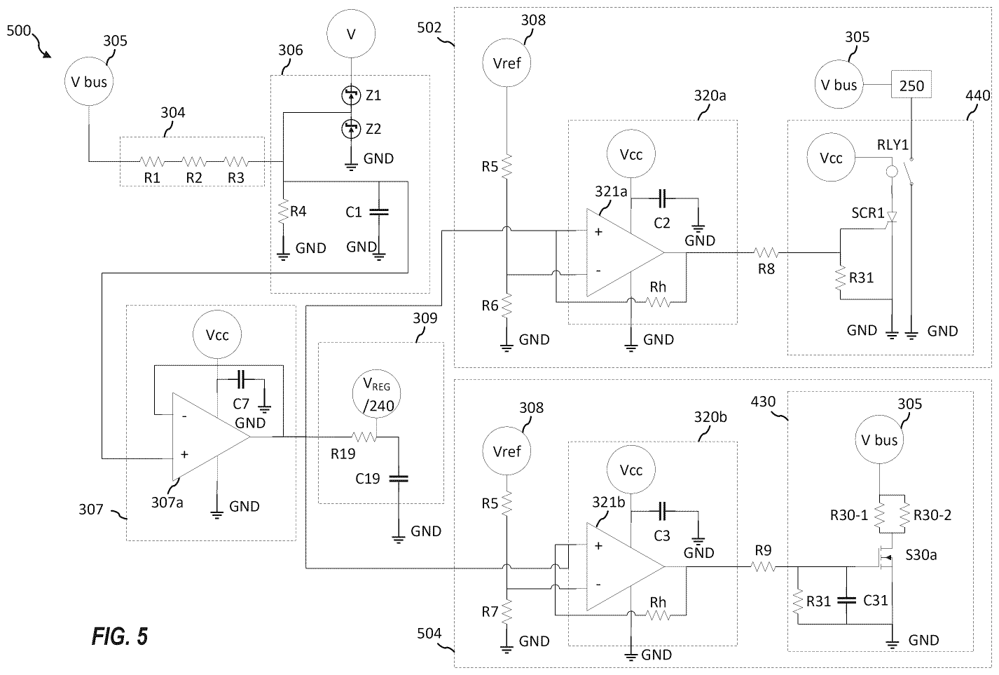

FIG. 5 depicts an illustrative diagram 500 of an implementation of the power management circuitry 210 (FIG. 2) in a wireless powered appliance 102 (FIG. 1). In particular, the diagram depicts one example of the power level detection circuit 220, 320 electrically coupled to the power transition stabilizer circuit 230, 330 and one or more appliance components 250 of the wireless powered appliance 102 (FIG. 1). It should be understood that the diagram 500 depicts an example and that other implementations and/or other components may be included in the implement of the power management circuitry in a wireless powered appliance 102.

As many of the components depicted in the diagram 500 have been described in detail herein, for brevity they will not be discussed in detail again with reference to FIG. 5.

In certain aspects, the power management circuitry 210 may include a voltage divider circuit 304 electrically coupled to a noise filter 306. The output of the noise filter may be electrically coupled to a buffer circuit 307. The buffer circuit 307 may be a voltage follower or voltage buffer type circuit. The buffer circuit 307 is prevents the voltage output from the voltage divider circuit 304 and/or the noise filter 306 from being affected by changes to the loads (e.g., the one or more electrical loads applied to the circuit. The buffer circuit 307 may include an operational amplifier 307a and other components, for example, capacitors C7, resistors (not shown), and/or the like.

In certain aspects, the power management circuitry 210 may include a voltage monitoring circuit 309, for example, including a resistor R19 and a capacitor C19 as depicted. As discussed herein above, the transition time of the electrical power corresponding to the supply voltage 305 may be measured by the controller 240. For example, the controller 240 may measure the rate of change (e.g., the transition time) in voltage, V, on the capacitor C17 to determine the corresponding transition time of the electrical power.

In the diagram 500 of the implementation of the power management circuitry 210, the power management circuitry 210 includes two branches, a first branch 502 and a second branch 504. The first branch 502 includes a power level detection circuit 320a configured to generate an output signal through resistor R8 when the input voltage at the positive input terminal (+) exceeds a first threshold. The power level detection circuit 320a is electrically coupled to an electrical load circuit 440. In the present instance, the electrical load circuit 440 is similar to the power transition stabilizer circuits 230, but instead of electrically connecting one or more electrical loads (e.g., a load resistor R30), the electrical load circuit 440 drives activation or electrical coupling of an appliance component 250. For example, the electrical load circuit 440 may include a silicon controlled rectifier SCR1. When a gate voltage of the silicon controlled rectifier SCR1 meets or exceeds a turn on voltage, the silicon controlled rectifier SCR1 like a diode becomes forward-biased such that current begins to flow. The flowing current activates a relay RLY1 causing the appliance component 250 to activate. While it is understood that in some aspects the silicon controlled rectifier SCR1 may be replaced with another type of switching device, the silicon controlled rectifier SCR1 is capable of latching such that it may remain in an ON state so that the relay RLY1 can remain ON even in the presence of noise on the output signal driving the the silicon controlled rectifier SCR1. For example, the electrical load circuit 440 may be one of the power transition stabilizer circuits 430 depicted and described with reference to FIG. 4B or 4C.

The second branch 504 includes a power level detection circuit 320b configured to generate an output signal through resistor R9 when the input voltage at the positive input terminal (+) exceeds a second threshold. The second threshold may be set to a voltage value that is greater than the voltage value of the first threshold. Accordingly, the second branch 504 may operate as the power absorption circuit when the electrical power generated by the wireless power receiver 104 is greater than an amount that is utilized by the appliance component 250, for example, during a load step transition event. The second branch 504, as illustrated in FIG. 5, operates in a manner consistent to the power level detection circuit 320b depicted and described with reference to FIG. 3A, which is electrically coupled to a power transition stabilizer circuit 430 (e.g., 430a or 430b depicted and described with reference to FIG. 4A. In the present implementation, the second branch 504 may operate to absorb electrical power that is in excess of the electrical power needed to drive the appliance component 250.

By way of a practical example, but without limitation, the appliance component 250 may be a heater coil. The first threshold, which is configured to activate the relay RLY1, is set to a value less than the second threshold corresponding to the fast acting power transition stabilizer circuit 430. For example, the first threshold may represent a VBus voltage of approximately 425 volts, which is higher than the expected in normal operating voltage, for example, of 400 volts. The

[symbol]

The low threshold value of the first threshold provides the relay RLY1 a head start in mechanically closing the switch portion of the relay, which may be a few milliseconds of time, to reduce the amount of time that the electrical load (e.g., resistor R30-1 and/or R30-2) needs to absorb power.

The second branch, which includes the fast acting power transition stabilizer circuit 430, may include a power level detection circuit 320b configured to generate an output signal when the second threshold is exceeded. The second threshold may have a value corresponding to the VBus having a voltage of 445 volts or more. To protect circuity, the second threshold is set to a value below voltage rating of components connected to VBus (e.g., below capacitors rated at 450 volts and/or 500 volts). The comparators 321a, 321b may have a push-pull output in order to turn the one or more electronic switches S30a, such as a MOSFET transistor ON fast in an effort to prevent damage to the one or more electronic switches S30a. Additionally, in certain aspects the electrical load may include one or more parallel resistors R30-1 and/or R30-2 to share the pulsed power dissipation and reduce the voltage VBus. Optionally, a single resistor may be utilized.

### Example Methods for Power Management of a Wireless Powered Appliance

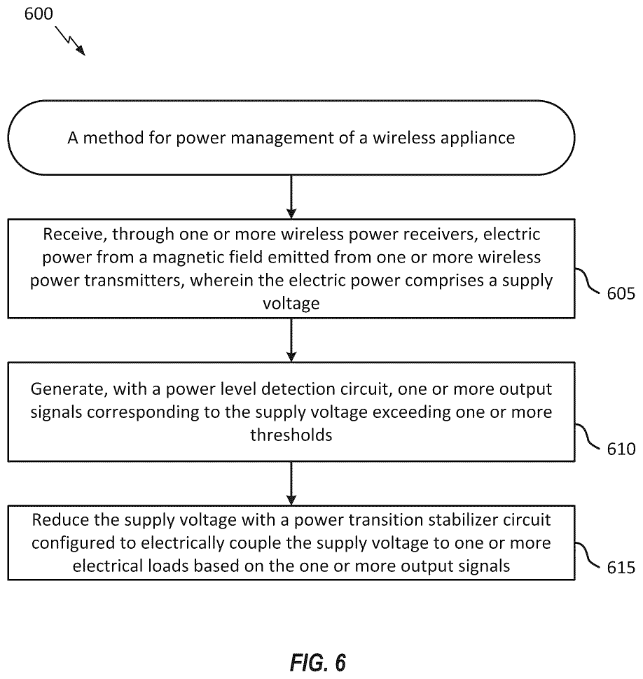

FIG. 6 shows a method 600 for power management of a wireless powered appliance, such as a wireless powered appliance 102 of FIG. 1.

Method 600 begins at block 605 with receiving, through one or more wireless power receivers, electric power from a magnetic field emitted from one or more wireless power transmitters, wherein the electric power comprises a supply voltage. For example, block 605 may correspond to wireless power receiver 104 generating electrical power from the magnetic field 203 as discussed with reference to FIGS. 1-2.

Method 600 then proceeds to block 610 with generating, with a power level detection circuit, one or more output signals corresponding to the supply voltage exceeding one or more thresholds. For example, block 610 may correspond to the power level detection circuits 320a, 320b, 320c as discussed with reference to FIGS. 3A-3B.

Method 600 then proceeds to block 615 with reducing the supply voltage with a power transition stabilizer circuit configured to electrically couple the supply voltage to one or more electrical loads based on the one or more output signals. For example, block 615 correspond to the power transition stabilizer circuits 330a, 330b as discussed with reference to FIGS. 4A-4C.

In one aspect, method 600 further includes comparing a respective reference voltage corresponding to a respective one of the one or more thresholds and the supply voltage, and generating respective ones of the one or more output signals based on the supply voltage exceeding the respective one of the one or more thresholds.

In one aspect, each of the one or more thresholds corresponds to a different threshold value.

In one aspect, the power level detection circuit further comprises a hysteresis resistor coupled to a positive input terminal and an output terminal.

In one aspect, the step of generating the one or more output signals further comprises: comparing, with a first comparator, the supply voltage to a first reference voltage corresponding to a first threshold of the one or more thresholds; generating a first output signal based on the supply voltage exceeding the first reference voltage; comparing, with a second comparator, the supply voltage to a second reference voltage corresponding to a second threshold of the one or more thresholds, wherein the second reference voltage is greater than the first reference voltage; and generating a second output signal based on the supply voltage exceeding the second reference voltage.

In one aspect, the power level detection circuit further comprises: a voltage divider circuit configured to divide a common reference voltage into the first reference voltage and the second reference voltage.

In one aspect, the power level detection circuit comprises: a Zener diode and a resistor, wherein: a cathode of the Zener diode is configured to receive the supply voltage; and an anode of the Zener diode is coupled to a first end of the resistor thereby defining an output terminal for the one or more output signals.

In one aspect, the output terminal corresponds to a high value when the supply voltage exceeds a breakdown voltage of the Zener diode.

In one aspect, the power level detection circuit further comprises: a first Schottky diode and a second Schottky diode electrically coupled to the Zener diode and configured to bound the one or more output signals within a voltage logic range, wherein: the anode of the Zener diode is coupled an anode of the first Schottky diode and a cathode of the second Schottky diode; a reference voltage supply is coupled to a cathode of the first Schottky diode; and an anode of the second Schottky diode and a second end of the resistor are coupled to ground.

In one aspect, the power transition stabilizer circuit comprises: a switching device electrically coupled to one or more output terminals and selectively activated based on the one or more output signals, and the one or more electrical loads are configured to reduce the supply voltage based on activation of the switching device that completes a conductive path from the one or more electrical loads to ground.

In one aspect, the one or more electrical loads comprise one or more resistors.

In one aspect, the one or more resistors comprise a resistance value between about 28 ohms and 33 ohms.

In one aspect, method 600 further includes receiving, with a pulse extender circuit, the one or more output signals; and causing, with the pulse extender circuit, the one or more electrical loads to remain electrically coupled after at least one of the one or more output signals decreases below one of the one or more thresholds.

In one aspect, method 600 may include measuring, with a controller, a rate of change of the electric power, wherein the rate of change indicates a power overshoot value, and signaling the power transition stabilizer circuit to electrically couple respective ones of the one or more electrical loads that correspond to the power overshoot value, wherein the respective ones of the one or more electrical loads electrically couple to the one or more wireless power receivers to reduce the electric power.

Note that FIG. 6 is just one example of a method, and other methods including fewer, additional, or alternative operations are possible consistent with this disclosure.

All definitions, as defined and used herein, should be understood to control over dictionary definitions, definitions in documents incorporated by reference, and/or ordinary meanings of the defined terms.

The indefinite articles “a” and “an,” as used herein in the specification and in the claims, unless clearly indicated to the contrary, should be understood to mean “at least one. ” The phrase “and/or,” as used herein in the specification and in the claims, should be understood to mean “either or both” of the elements so conjoined, i.e., elements that are conjunctively present in some cases and disjunctively present in other cases. Multiple elements listed with “and/or” should be construed in the same fashion, i.e., “one or more” of the elements so conjoined. Other elements may optionally be present other than the elements specifically identified by the “and/or” clause, whether related or unrelated to those elements specifically identified. Thus, as a non-limiting example, a reference to “A and/or B”, when used in conjunction with open-ended language such as “comprising” can refer, in one embodiment, to A only (optionally including elements other than B); in another embodiment, to B only (optionally including elements other than A); in yet another embodiment, to both A and B (optionally including other elements); etc.

As used herein in the specification and in the claims, “or” should be understood to have the same meaning as “and/or” as defined above. For example, when separating items in a list, “or” or “and/or” shall be interpreted as being inclusive, i.e., the inclusion of at least one, but also including more than one, of a number or list of elements, and, optionally, additional unlisted items. Only terms clearly indicated to the contrary, such as “only one of” or “exactly one of,” or, when used in the claims, “consisting of,” will refer to the inclusion of exactly one element of a number or list of elements. In general, the term “or” as used herein shall only be interpreted as indicating exclusive alternatives (i.e. “one or the other but not both”) when preceded by terms of exclusivity, such as “either,” “one of,” “only one of,” or “exactly one of. ” “Consisting essentially of,” when used in the claims, shall have its ordinary meaning as used in the field of patent law.

As used herein in the specification and in the claims, the phrase “at least one,” in reference to a list of one or more elements, should be understood to mean at least one element selected from any one or more of the elements in the list of elements, but not necessarily including at least one of each and every element specifically listed within the list of elements and not excluding any combinations of elements in the list of elements. This definition also allows that elements may optionally be present other than the elements specifically identified within the list of elements to which the phrase “at least one” refers, whether related or unrelated to those elements specifically identified. Thus, as a non-limiting example, “at least one of A and B” (or, equivalently, “at least one of A or B,” or, equivalently “at least one of A and/or B”) can refer, in one embodiment, to at least one, optionally including more than one, A, with no B present (and optionally including elements other than B); in another embodiment, to at least one, optionally including more than one, B, with no A present (and optionally including elements other than A); in yet another embodiment, to at least one, optionally including more than one, A, and at least one, optionally including more than one, B (and optionally including other elements); etc.

It should also be understood that, unless clearly indicated to the contrary, in any methods claimed herein that include more than one step or act, the order of the steps or acts of the method is not necessarily limited to the order in which the steps or acts of the method are recited.

In the claims, as well as in the specification above, all transitional phrases such as “comprising,” “including,” “carrying,” “having,” “containing,” “involving,” “holding,” “composed of,” and the like are to be understood to be open-ended, i.e., to mean including but not limited to. Only the transitional phrases “consisting of” and “consisting essentially of” shall be closed or semi-closed transitional phrases, respectively, as set forth in the United States Patent Office Manual of Patent Examining Procedures, Section 2111.03.

It is to be understood that the embodiments are not limited in its application to the details of construction and the arrangement of components set forth in the description or illustrated in the drawings. The invention is capable of other embodiments and of being practiced or of being carried out in various ways. Unless limited otherwise, the terms “connected,” “coupled,” “in communication with,” and “mounted,” and variations thereof herein are used broadly and encompass direct and indirect connections, couplings, and mountings. In addition, the terms “connected” and “coupled” and variations thereof are not restricted to physical or mechanical connections or couplings.

The foregoing description of several embodiments of the invention has been presented for purposes of illustration. It is not intended to be exhaustive or to limit the invention to the precise steps and/or forms disclosed, and obviously many modifications and variations are possible in light of the above teaching.

What is claimed is:

1. A wireless powered appliance, comprising:
one or more wireless power receivers configured to generate electric power from a magnetic field emitted from one or more wireless power transmitters, wherein the electric power comprises a supply voltage;
a power level detection circuit comprising circuit components configured to generate one or more output signals at one or more output terminals, wherein the one or more output signals correspond to the supply voltage exceeding one or more thresholds; and
a power transition stabilizer circuit configured to receive the one or more output signals from the power level detection circuit and the supply voltage from the one or more wireless power receivers, the power transition stabilizer circuit comprising one or more electrical loads configured to electrically couple to the supply voltage based on the one or more output signals such that the supply voltage is reduced by the one or more electrical loads.

2. The wireless powered appliance of claim 1, wherein the power level detection circuit comprises:
one or more comparators, wherein each of the one or more comparators is configured to:
compare a respective reference voltage corresponding to a respective one of the one or more thresholds and the supply voltage, and
generate respective ones of the one or more output signals based on the supply voltage exceeding the respective one of the one or more thresholds.

3. The wireless powered appliance of claim 1, wherein each of the one or more thresholds corresponds to a different threshold value.

4. The wireless powered appliance of claim 1, wherein the power level detection circuit further comprises a hysteresis resistor coupled to a positive input terminal and an output terminal.

5. The wireless powered appliance of claim 1, wherein the power level detection circuit comprises:
a first comparator configured to compare the supply voltage to a first reference
voltage corresponding to a first threshold of the one or more thresholds and generate a first output signal based on the supply voltage exceeding the first reference voltage; and
a second comparator configured to compare the supply voltage to a second reference voltage corresponding to a second threshold of the one or more thresholds, the second reference voltage is greater than the first reference voltage and generate a second output signal based on the supply voltage exceeding the second reference voltage.

6. The wireless powered appliance of claim 5, wherein the power level detection circuit further comprises: a voltage divider circuit configured to divide a common reference voltage into the first reference voltage and the second reference voltage.

7. The wireless powered appliance of claim 1, wherein the power level detection circuit comprises: a Zener diode and a resistor, wherein:
a cathode of the Zener diode is configured to receive the supply voltage; and
an anode of the Zener diode is coupled to a first end of the resistor thereby defining an output terminal for the one or more output signals.

8. The wireless powered appliance of claim 7, wherein the one or more output signals generated at the output terminal corresponds to a high value when the supply voltage exceeds a breakdown voltage of the Zener diode.

9. The wireless powered appliance of claim 7, wherein the power level detection circuit further comprises:
a first Schottky diode and a second Schottky diode electrically coupled to the Zener diode and configured to bound the one or more output signals within a voltage logic range, wherein:
the anode of the Zener diode is coupled an anode of the first Schottky diode and a cathode of the second Schottky diode;
a reference voltage supply is coupled to a cathode of the first Schottky diode; and
an anode of the second Schottky diode and a second end of the resistor are coupled to ground.

10. The wireless powered appliance of claim 1, wherein the power transition stabilizer circuit comprises:
a switching device electrically coupled to the one or more output terminals and selectively activated based on the one or more output signals, and
the one or more electrical loads are configured to reduce the supply voltage based on activation of the switching device that completes a conductive path from the one or more electrical loads to ground.

11. The wireless powered appliance of claim 1, wherein the one or more electrical loads comprise one or more resistors.

12. The wireless powered appliance of claim 1, wherein the one or more electrical loads comprise an impedance value corresponding to an equivalent impedance of an appliance component.

13. The wireless powered appliance of claim 1, further comprising a pulse extender circuit, wherein the pulse extender circuit is configured to:
receive the one or more output signals; and
cause the one or more electrical loads to remain electrically coupled after at least one of the one or more output signals decreases below one of the one or more thresholds.

14. The wireless powered appliance of claim 1, further comprising:
a controller electrically coupled to the power level detection circuit and the power transition stabilizer circuit, the controller configured to:
measure a rate of change of the electric power, wherein the rate of change indicates a power overshoot value, and
signal the power transition stabilizer circuit to electrically couple respective ones of the one or more electrical loads that correspond to the power overshoot value, wherein the respective ones of the one or more electrical loads electrically couple to the one or more wireless power receivers to reduce the electric power.

15. A method for power management of a wireless powered appliance, the method comprising:
receiving, through one or more wireless power receivers, electric power from a magnetic field emitted from one or more wireless power transmitters, wherein the electric power comprises a supply voltage;
generating, with a power level detection circuit, one or more output signals corresponding to the supply voltage exceeding one or more thresholds; and
reducing the supply voltage with a power transition stabilizer circuit configured to electrically couple the supply voltage to one or more electrical loads based on the one or more output signals.

16. The method of claim 15, further comprising:
comparing a respective reference voltage corresponding to a respective one of the one or more thresholds and the supply voltage, and
generating respective ones of the one or more output signals based on the supply voltage exceeding the respective one of the one or more thresholds.

17. The method of claim 15, wherein each of the one or more thresholds corresponds to a different threshold value.

18. The method of claim 15, wherein the step of generating the one or more output signals further comprises comparing, with a first comparator, the supply voltage to a first reference voltage corresponding to a first threshold of the one or more thresholds;
generating a first output signal based on the supply voltage exceeding the first reference voltage;
comparing, with a second comparator, the supply voltage to a second reference voltage corresponding to a second threshold of the one or more thresholds, wherein the second reference voltage is greater than the first reference voltage; and
generating a second output signal based on the supply voltage exceeding the second reference voltage.

19. The method of claim 15, wherein the power level detection circuit comprises: a Zener diode and a resistor, wherein:
a cathode of the Zener diode is configured to receive the supply voltage; and
an anode of the Zener diode is coupled to a first end of the resistor thereby defining an output terminal for the one or more output signals.

20. The method of claim 15, further comprising:
receiving, with a pulse extender circuit, the one or more output signals; and
causing, with the pulse extender circuit, the one or more electrical loads to remain electrically coupled after at least one of the one or more output signals decreases below one of the one or more thresholds.
